(19) United States
(12) Patent Application Publication
(10) Pub. No.: US 2021/0382216 A1
(43) Pub. Date: Dec. 9, 2021

(54) RETARDATION FILM, A CIRCULAR POLARIZER AND AN ELECTROLUMINESCENT DISPLAY COMPRISING THE SAME

(71) Applicant: BenQ Materials Corporation, Taoyuan (TW)

(72) Inventor: Chao-Che Chang, Taoyuan (TW)

(21) Appl. No.: 17/109,192

(22) Filed: Dec. 2, 2020

(30) Foreign Application Priority Data
Jun. 9, 2020 (TW) 109119270

(51) Int. Cl. G02B 5/30; H01L 51/52; G02F 1/1335; G02F 1/13363

(52) U.S. Cl. CPC G02B 5/3083; G02B 5/305; H01L 51/5293; G02F 2202/40; G02F 1/133637; G02F 2202/022; G02F 2202/04; G02F 1/133541

(57) ABSTRACT

A retardation film is provided. The retardation film comprises a water-soluble polymer matrix and at least a water-soluble dichroic dye dispersed in the water-soluble polymer matrix. The water-soluble dichroic dye has a molecular long-axis aligned along a stretching direction of the water-soluble polymer matrix. The water-soluble dichroic dye has a maximum absorption wavelength between 550 nm and 650 nm, and has a dichroic ratio greater than 10 at the maximum absorption wavelength. The refractive index and the corresponding retardation value of the retardation film in long-wavelength band can be adjusted individually by adding the water-soluble dichroic dye with the maximum absorption wavelength between 550 nm and 650 nm in the water-soluble polymer matrix and arranging the water-soluble dichroic dye in an order. Therefore, reverse wavelength dispersion is generated.

### RELATED APPLICATIONS

This application claims priority to Taiwan Application Serial Number 109119270 filed on Jun. 9, 2020, which is herein incorporated by reference.

### BACKGROUND OF THE INVENTION

### Field of the Invention

The invention relates to a retardation film, and in particular to a retardation film having reverse wavelength dispersion, a circular polarizer using the retardation film and an electroluminescent display comprising the circular polarizer. The retardation film provides the electroluminescent display including high-reflectivity electrodes with a better anti-reflective property and improves the problem of not being able to form a pure dark state image resulting from color-shift of the reflected light.

### Description of the Related Art

Electroluminescent displays including millimeter-scaled small-pitch light-emitting diode displays (Small-pitch LED Displays), sub-millimeter-scaled light-emitting diode displays (Mini LED Displays), micron light-emitting diode displays (Micro LED Displays) or organic light-emitting diode displays (OLED Displays), etc., have the advantages of self-luminescence, wide viewing angle, fast response time, high brightness, high contrast, high lumen efficiency, low operating voltage, small thickness, and flexibility. Therefore, they are foreseeable to become mainstream display products for outdoor information billboards, car display devices or handheld mobile devices and other applications in various situations.

With the increasing requirements for the hue of the display area of handheld mobile devices such as mobile phones in dark state, it is expected to achieve a consistent pure black state, so that the retardation film used with the circular polarizer of the light-emitting surface of the electroluminescent display must have compensation characteristics for each light wavelength band to avoid color-shift of reflected light. A known circular polarizer is structured by, for example, a linear polarizer with a quarter-wavelength (¼λ) retardation film. However, these retardation films are difficult to maintain the in-plane retardation value of ¼λ in the longer wavelength band, especially between 565 nm to 715 nm, and deviate more at the short-wavelength band of blue-green light such as 450 nm to 550 nm because the ¼λ retardation film is generally made from a polymer material by casting or stretching methods and the in-plane retardation difference R₀ is a positive wavelength dispersion that decreases with the increasing wavelength, or maintains a flat wavelength dispersion close to a constant value as increasing wavelength, rather than a reverse wavelength dispersion that increases with increasing wavelength, thereby the long-wavelength reflected light will leak and increases the reflectivity to result in color-shift of dark state images. Therefore, the in-plane retardation of the ¼λ retardation film in the circular polarizer should preferably conform to the reverse wavelength dispersion characteristics to improve the above-mentioned defects.

Moreover, the wavelength dispersion of the retardation film derives from the inherent birefringence characteristic of the polymer material itself, which is difficult to be significantly changed by the manufacturing process thereof. Conventional methods for preparing retardation films with reverse wavelength dispersion properties include, for example, polymerizing polymerized monomers with different birefringence properties and stretching them into a film, modifying the polymerized monomers to have side chains with a refractive index different from that in the stretching direction, or mixing liquid crystal molecules into a polymer film. However, polymerization of polymerized monomers or modification of polymerized monomers will increase the glass transition temperature Tg of the formed polymer substrate, and change the properties of polymer elongation and shrinkage stress, etc., which will significantly affect the processing conditions and make subsequent wrinkle defects appeared on the finished products. Generally speaking, the maximum absorption band of the side chains used to modify the polymerized monomers in retardation films to change the non-optical axis direction refractive index is usually also toward to the short-wavelength band, so it can only reduce the in-plane retardation of wavelengths from 450 nm to 550 nm. The wavelength band greater than 550 nm, especially the wavelength in the range from 565 nm to 715 nm is difficult to affect by the modification of the side chain of the polymerized monomers. Therefore, the modification rate of the side chains of the polymerized monomers must be significantly enhanced to increase the in-plane retardation in the wavelength range from 565 nm to 715 nm to the ideal quarter-wavelength value, which will excessively reduce the in-plane retardation in the short-wavelength band, such as 450 nm. For example, the ratio of the in-plane retardation of 450 nm to the in-plane retardation of 550 nm is lower than the ideal value of the wavelength ratio of 0.82, and the ideal quarter-wavelength value cannot be maintained, which is easy to make the electroluminescent display with a circularly polarizer having the retardation film appear a dark state image color-shift. When liquid crystal molecules are mixed in the polymer film, the liquid crystal molecules become liquid and phase separate from the polymer when the temperature of the stretching process exceeds the phase transition temperature of the liquid crystal molecules, which will increase the haze of the film generated thereafter, and affects the clarity of the retardation film. In addition, since the conventionally known polymer materials and liquid crystal molecules used in retardation films with reverse wavelength dispersion characteristics are usually water-insoluble, a large amount of organic solvents must be used in the manufacturing process and the temperature must be increased to facilitate the extension, which derives many issues like solvent recycling.

Accordingly, this present invention provide a retardation film manufactured by an aqueous process, and the retardation film has an excellent in-plane retardation property in the long-wavelength band to provide the electroluminescent display having a circular polarizer with the retardation film with an excellent anti-reflective effect, and avoid the color-shift problem of the dark state images caused by the leakage of the reflected light in the long-wavelength band to enhance the displaying qualities of the electroluminescent display.

### SUMMARY OF THE INVENTION

An aspect of this invention is to provide a retardation film, comprising a water-soluble polymer matrix and at least a water-soluble dichroic dye dispersed in the water-soluble polymer matrix, wherein the water-soluble dichroic dye has a molecular long-axis aligned along a stretching direction of the water-soluble polymer matrix, and the water-soluble dichroic dye has a maximum absorption wavelength between 550 nm and 650 nm, and has a dichroic ratio greater than 10 at the maximum absorption wavelength, and the retardation film satisfies a formula as follows:

R₀(650 nm)/R₀(550 nm)>1

wherein R₀(550 nm) is the in-plane retardation of the retardation film at the wavelength of 550 nm, and R₀(650 nm) is the in-plane retardation of the retardation film at the wavelength of 650 nm.

In an embodiment of the retardation film of this present invention, wherein the in-plane retardation of the retardation film preferably satisfies a formula as follows: 1.30>R₀(650 nm)/R₀(550 nm)>1.05.

In an embodiment of the retardation film of this present invention, wherein the retardation film satisfies a formula as follows: R₀(450 nm)/R₀(550 nm)≤1, wherein R₀(450 nm) is an in-plane retardation at a wavelength of 450 nm.

In an embodiment of the retardation film of this present invention, wherein the water-soluble polymer matrix is selected from one of the group consisting of polyol polymer, polyester polyol, polyurethane and polysiloxane, or combinations thereof.

In an embodiment of the retardation film of this present invention, wherein the water-soluble dichroic dye is an azo compound or a salt thereof.

In an embodiment of the retardation film of this present invention, wherein the content of the water-soluble dichroic dye relative to the water-soluble polymer matrix ranges from 0.1 wt % to 0.5 wt %.

In an embodiment of the retardation film of this present invention, wherein the thickness of the retardation film ranges from 5 μm to 100 μm.

Another aspect of this invention is to provide a circular polarizer, comprising one of the above-mentioned retardation films, and a linear polarizer disposed on the light-exit side of the retardation film.

Another aspect of this invention is to provide an electroluminescent display, comprising: an electroluminescent display panel; and one of the above-mentioned circular polarizer disposed on a light-emitting side of the electroluminescent display panel.

In an embodiment of the electroluminescent display of this present invention, the electroluminescent display panel is a millimeter-scaled small-pitch light-emitting diode display panel, a sub-millimeter-scaled light-emitting diode display panel, a micron light-emitting diode display panel or an organic light-emitting diode display panel.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIG. 1 illustrates a cross-sectional view of a circular polarizer according one embodiment of this present invention.

FIG. 2 illustrates a cross-sectional view of an electroluminescent display according one embodiment of this present invention.

### DETAILED DESCRIPTION OF THE INVENTION

The detailed description provided below in connection with the appended drawings is intended as a description of the present examples and is not intended to represent the only forms in which the present example may be constructed or utilized. The description sets forth the functions of the example and the sequence of steps for constructing and operating the example. However, the same or equivalent functions and sequences may be accomplished by different examples.

In the following description, numerous specific details are described in detail in order to enable the reader to fully understand the following examples. However, embodiments of the present invention may be practiced in case no such specific details. In other cases, in order to simplify the drawings the structure of the apparatus known only schematically depicted in figures.

This invention provides a retardation film, comprising a water-soluble polymer matrix and at least a water-soluble dichroic dye dispersed in the water-soluble polymer matrix, wherein the water-soluble dichroic dye has a molecular long-axis aligned along a stretching direction of the water-soluble polymer matrix, and the water-soluble dichroic dye has a maximum absorption wavelength between 550 nm and 650 nm, and has a dichroic ratio greater than 10 at the maximum absorption wavelength, and the in-plane retardation of the retardation film satisfies a formula as follows:

R₀(650 nm)/R₀(550 nm)>1

wherein R₀(550 nm) is the in-plane retardation of the retardation film at the wavelength of 550 nm, and R₀(650 nm) is the in-plane retardation of the retardation film at the wavelength of 650 nm.

The term “in-plane retardation R₀” used herein refers to a product of the thickness d and the difference between the extraordinary refractive index nₑ and the ordinary refractive index nₒ of the retardation film calculated by the formula: R₀=(nₑ−nₒ)*d, wherein R₀(550 nm) representing the in-plane retardation measured at the wavelength of 550 nm is a typical in-plane retardation. However, R₀(550 nm) can't represent all compensation results of a retardation at various wavelengths because the polymer forming the retardation film has different dispersion wavelength depending on the wavelength of the incident light. When a selected polymer material is stretched and the in-plane retardation R₀ at a wavelength of 550 nm and the in-plane retardation R₀ at a wavelength of 650 nm thereof are almost equal, that is R₀(650 nm)/R₀(550 nm)=1±0.01, then the polymer can be classified as a material having a flat dispersion at wavelength between 550 nm and 650 nm.

Suitable water-soluble polymer matrix for the retardation film of this present invention is selected from one of the group consisting of polyol polymer, polyester polyol, polyurethane and polysiloxane, or combinations thereof. Since the water-soluble polymer matrix is soluble in water, which can be stretched uniaxially or biaxially without adding any organic solvent, to serve as a carrier for water-soluble dichroic dyes and as an alignment layer for aligning the water-soluble dichroic dyes, wherein the axis with a higher stretching ratio is defined as the main stretching direction of the water-soluble polymer matrix. The conventional polymer materials, especially those with positive wavelength dispersion, have larger retardation deviations in long-wavelength bands. As the in-plane retardation of the stretched water-soluble polymer matrix reaches a flat wavelength dispersion satisfying the formula: R₀(650 nm)/R₀(550 nm)≈1 in the long-wavelength band, the polymer material is sufficient to be used for the retardation film of the present invention. In the short-wavelength band, the water-soluble polymer matrix preferably has a flat wavelength dispersion or a reverse wavelength dispersion to further satisfy the relational of formula: R₀(450 nm)/R₀(550 nm)≤1 when the retardation film is applied to electroluminescent displays to maintain or reduce the reflectivity in the short-wavelength band, where R₀(450 nm) is the in-plane retardation corresponding to the wavelength of 450 nm. Moreover, because the theoretical value of the ration of the center wavelength 450 nm of blue light over the center wavelength 550 nm of green light is 0.82, the in-plane retardation of the retardation film according to an embodiment of this present invention preferably satisfies the relationship of the formula: 0.82<R₀(450 nm)/R₀(550 nm)≤1 in order to avoid the retardation in short-wavelength band too low to provide the electroluminescent display with more leakage of short-wavelength light of high energy in dark state.

The water-soluble dichroic dye of the retardation film according to this present invention has a maximum absorption wavelength between 550 nm and 650 nm, and has a dichroic ratio greater than 10 at the maximum absorption wavelength. When the maximum absorption wavelength of the water-soluble dichroic dye is between 550 nm and 650 nm, the difference of refractive index is also more significant at the wavelength band thereof. When the dichroic ratio of the water-soluble dichroic dye at the maximum absorption wavelength is greater than 10, the refractive index difference between the stretch direction and the direction perpendicular to the stretch direction can be easily changed by the stretching and alignment of the water-soluble polymer matrix to enhance the in-plane retardation of the retardation film in long-wavelength band to sufficiently cover the visible light of 565 m to 715 nm, thereby a retardation film with reverse wavelength dispersion in long-wavelength band can be obtained.

Suitable dichroic dyes used in the retardation film of this invention can be for example but not limited to azo compounds or salts thereof, and preferably the azo compounds represented by a formula as follows:

Ar₁—N═N [symbol] Ar₂—N═N [symbol] ₙ—Ar₃

wherein Ar₁ is a naphthyl group substituted with a sulfonyl hydroxide group and/or a sulfonic acid alkoxy group, wherein the alkoxy group is a C₁-C₅ alkoxy group; Ar₂ is phenyl group substituted with a C₁-C₄ alkyl group and/or C₁-C₄ alkoxy group; Ar₃ is a naphtholsulfonic acid group substituted with anilino group or naphtholsulfonic acid group substituted with a methoxyaniline group; n is an integer from 1 to 3.

The amount of the water-soluble dichroic dye of the present retardation film is 0.1 wt % to 0.5 wt % based on the weight of the water-soluble polymer matrix. Such an amount of the water-soluble dichroic dye is sufficient to generate effective retardation values for the long-wavelength band. Because the amount of the water-soluble dichroic dye is low (<1 wt %), the effect on the intensity of the bright-state images of electroluminescent displays is very minor. Unlike the conventional modified polymer materials, the phase difference in the short-wavelength band will be excessively reduced to result in a color-shift of reflection light in dark state again. Moreover, because the ideal value of the ration of the center wavelength 650 nm of red light over the center wavelength 550 nm of green light is 1.18, the in-plane retardation of the retardation film according to an embodiment of this present invention preferably satisfies the formula: 1.30>R₀(650 nm)/R₀(550 nm)>1.05 to provide the electroluminescent display with a suitable retardation in long-wavelength band to reduce the light leakage at long-wavelength band.

In another embodiment of this invention, the thickness of the retardation film ranges from 5 μm to 100 μm to provide the retardation film with a predetermined retardation value.

This invention also disclose a method of manufacturing a retardation film comprising the steps of coating a solution of a water-soluble polymer mixed with a dichroic dye onto a carrier substrate to form a coating layer, curing the coating layer and dry stretching thereafter, and peeling off the carrier substrate to generate a retardation film.

In a preferred embodiment of the method of manufacturing a retardation film according to this invention, the dried coating layer is stretched three-times in a stretching speed of 0.1 m/min to avoid broken caused by over stretching and undesired retardation caused by insufficient stretching. In another preferred embodiment of the method of manufacturing a retardation film according to this invention, the coating layer is preferably dried at 80° C. to 110° C., and more preferably dried at 85° C. to 110° C.

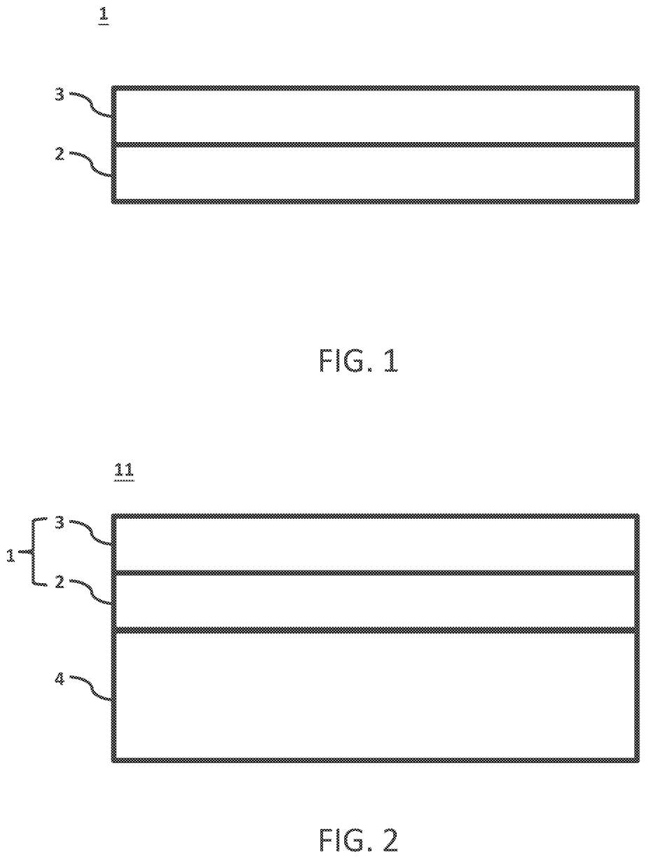

The retardation film of this invention can be bonded to a linear polarizer to generate a circular polarizer. As shown in FIG. 1, a cross-sectional view of a circular polarizer according to this invention is illustrated. In FIG. 1, the circular polarizer 1 comprises one of the above-mentioned retardation films 2 and a linear polarizer 3 disposed on the light-exit side of the retardation film 2.

The linear polarizer 3 of the circular polarizer 1 can be one of the linear polarizer generally used on the display field, such as polymer films dyed with aligned dichroic dyes. Suitable linear polarizer can be hydrophilic polymer films dyed with dichroic iodine, wherein the hydrophilic polymer films can be for example but not limited to polyvinyl alcohol films, ethylene-vinyl acetate copolymer films, ethylene vinyl alcohol copolymer films, cellulous films and/or partial saponified cellulous films, or polyene alignment films such as dehydrated polyvinyl alcohol films, dechlorinated polyvinyl alcohol films or analogues thereof. In a preferred embodiment of this invention, the linear polarizer is a polyvinyl alcohol film dyed with dichroic iodine. The linear polarizer can be obtained by any conventional processes such as coating, and dry stretching or wet stretching thereafter, and the sequence of the processes and repeating times are not limited.

The circular polarizer can be used in the electroluminescent display. As shown in FIG. 2, a cross-sectional view of an electroluminescent display according to this present invention is illustrated. In FIG. 2, the electroluminescent display 11 comprises an above-mentioned circular polarizer 1 and an electroluminescent display panel 4, and the circular polarizer 1 is disposed on the light-exit side of the electroluminescent display panel 4 to reduce the external reflected light and act as a protective cover.

In an embodiment of the electroluminescent display 11 according to this present invention, the electroluminescent display panel 4 can be for example but not limited to a millimeter-scaled small-pitch light-emitting diode display panel (Small-pitch LED Display), a sub-millimeter-scaled light-emitting diode display panel (Mini LED Display), a micron light-emitting diode display panel (Micro LED Display) or organic light-emitting diode display panel (OLED Display). For the types of self-luminous display panels with highly reflective electrodes and resonant cavity, or even self-luminous display panels with integrated touch modules, conventional adhesion methods can be used, without the need to change the laminated structure of the electroluminescent display panel or by changing the packaging process to increase the internal quantum efficiency, and the effect of reducing the degree of light reflection and low color-shift can be achieved by attaching the circular polarizer 1 of the present invention onto the light-existing side of the electroluminescent display panel 4.

The detailed description provided below in connection with the appended drawings is intended as a description of the present examples and is not intended to represent the only forms in which the present example may be constructed or utilized. The description sets forth the functions of the example and the sequence of steps for constructing and operating the example. However, the same or equivalent functions and sequences may be accomplished by different examples.

### EXAMPLE

### Example 1

A solution prepared by dissolving 50 g of polyvinyl alcohol (PVA) powder (JC-40, having an average degree of polymerization of 4000, and a degree of saponification of 99 mol %, commercially obtained from Japan Vam & Poval Co., Ltd.) and 0.05 g of water-soluble azobiphenyl dichroic dye (Purple-150682, having a maximum absorption wavelength at 560 nm and a dichroic ratio of 18.7, commercially obtained from Orgchem Technologies Inc.) in water was coated onto a polyethylene terephthalate (PET) film to form a coating layer. The coating layer was cured in an oven at 90° C. for 15 minutes, and uniaxially stretched in a speed of 0.1 m/min at 90° C. for three times. After peeling off the PET film, a retardation film with a thickness of 8 μm was obtained.

The in-plane retardations of the obtained retardation film at various wavelengths were measured by a polarmeter (Axoscan, commercially obtained from Axometrics) and the measured in-plane retardations were shown in Table 1.

### Example 2

A retardation film with a thickness of 8 μm was manufactured by the process the same as described in Example1 except that the solution for coating was prepared by dissolving 50 g of polyvinyl alcohol (PVA) powder (JC-40) and 0.15 g of water-soluble azobiphenyl dichroic dye (Purple-150682) in water. The in-plane retardations of the obtained retardation film at various wavelengths were measured by the same manner as described in Example 1 and the measured in-plane retardations were shown in Table 1.

### Example 3

A retardation film with a thickness of 8 μm was manufactured by the process the same as described in Example 1 except that the solution for coating was prepared by dissolving 50 g of polyvinyl alcohol (PVA) powder (JC-40) and 0.25 g of water-soluble azobiphenyl dichroic dye (Purple-150682) in water. The in-plane retardations of the obtained retardation film at various wavelengths were measured by the same manner as described in Embodiment 1 and the measured in-plane retardations were shown in Table 1.

### Comparative Example

A retardation film with a thickness of 8 μm was manufactured by the process the same as described in Example 1 except that the solution for coating was prepared by dissolving 50 g of polyvinyl alcohol (PVA) powder (JC-40) in water without adding any water-soluble dichroic dye. The in-plane retardations of the obtained retardation film at various wavelengths were measured by the same manner as described in Example 1 and shown in Table

TABLE 1
In-plane retardation at various wavelengths and ratio thereof

| | | | | R₀ | R₀ |
|---|---|---|---|---|---|
| | | | | (450 nm)/ | (650 nm)/ |
| | R₀ | R₀ | R₀ | R₀ | R₀ |
| | (450 nm) | (550 nm) | (650 nm) | (550 nm) | (550 nm) |
| Comparative | 110.73 | 109.74 | 109.11 | 1.01 | 0.99 |
| Example | | | | | |
| Example 1 | 108.29 | 108.23 | 114.71 | 1.00 | 1.06 |
| Example 2 | 119.44 | 120.73 | 141.48 | 0.99 | 1.17 |
| Example 3 | 122.27 | 124.95 | 158.84 | 0.98 | 1.27 |

As shown in Table 1, the ratios of R₀(650 nm)/R₀(550 nm) of the retardation films of Examples 1 to 3 in long-wavelength band are of reverse wavelength dispersion. The ratios of R₀(650 nm)/R₀(550 nm) of the retardation films of Examples 2 and 3 are close to and overlap with the ideal value of 1.18, and have excellent enhancing efficiency of in-plane retardation R₀ at the wavelength of 650 nm to enhance R₀(650 nm) to a value close to the theoretical value of ¼λ. Therefore, it provides a tolerance to adjust the in-plane retardation by increasing its thickness. Moreover, as shown in Table 1, the ratios of R₀(450 nm)/R₀(550 nm) of the retardation films of Examples 1 to 3 at short-wavelengths demonstrate that they still maintain the flat wavelength dispersion or slight reverse wavelength dispersion characteristics as that of the PVA substrate without adding any dichroic dye. Therefore, in the present invention, the water-soluble dichroic dye with the maximum absorption wavelength in the long-wavelength band can be individually compensated for the retardation deviation in the long-wavelength band without excessively reducing the retardation value in the short-wavelength band.

Circular polarizers were obtained by respectively disposing the retardation films of Embodiments 2 and 3 and the Comparative Example to linear polarizer, wherein the angle between the optical axis of the retardation film and the absorption axis of the linear polarizer is 45°. These circular polarizers were respectively attached to a mirrored metal plate whose reflectivity is close to the same in all wavelengths to eliminate the difference in reflectivity of OLED panel materials produced by different manufacturers to measure circular polarizer's reducing effect of reflectivities of the visible light reflected by the highly reflective electrodes of the OLED panel. The reducing effect of reflectivities of the visible light was measured by a spectrophotometer (U4100, HITACHI) to measure the reflected light of the dark state black image formed after standard D65, which is a light source close to natural light, is irradiated on the circular polarizer attached to the mirrored metal plate, and then reflectivities of reflected light of various wavelengths at 5° incident angles were measured. The measured results are shown in Table 2.

TABLE 2
Reflectivities of reflected light of various wavelengths

| | R % | R % | R % |
|---|---|---|---|
| | (450 nm) | (550 nm) | (650 nm) |
| Comparative | 6.6 | 8.1 | 12.3 |
| Example | | | |
| Example 2 | 6.1 | 7.4 | 7.2 |
| Example 3 | 5.2 | 7.1 | 5.6 |

As shown in Table 2, the reflectivities in long-wavelength of 650 nm are effectively reduced by the circular polarizers of Examples 2 and 3. Similar to the measurement results of retardation shown in Table 1, the reflectivities in short-wavelength band are rarely affected by the circular polarizers of Examples 2 and 3. Consequently, the retardation film made by adding water-soluble dichroic dye to the water-soluble polymer matrix of the present invention can selectively adjust and increase the retardation in long-wavelength band to improve the color-shift of reflected light of the dark state black image of an electroluminescent display.

While the invention has been described by way of example(s) and in terms of the embodiments, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A retardation film, comprising:
a water-soluble polymer matrix;
at least a water-soluble dichroic dye dispersed in the water-soluble polymer matrix, wherein the water-soluble dichroic dye has a molecular long-axis aligned along a stretching direction of the water-soluble polymer matrix, wherein the water-soluble dichroic dye has a maximum absorption wavelength between 550 nm and 650 nm, and has a dichroic ratio greater than 10 at the maximum absorption wavelength;
wherein the retardation film satisfies a formula as follows:
R₀(650 nm)/R₀(550 nm)>1
wherein the R₀(550 nm) is an in-plane retardation at a wavelength of 550 nm, and the R₀(650 nm) is an in-plane retardation at a wavelength of 650 nm.

2. The retardation film as claimed in claim 1, wherein the retardation film preferably satisfies a formula as follows:
1.30>R₀(650 nm)/R₀(550 nm)>1.05

3. The retardation film as claimed in claim 1, wherein the retardation film preferably satisfies a formula as follows:
R₀(450 nm)/R₀(550 nm)≤1
wherein the R₀(450 nm) is an in-plane retardation at a wavelength of 450 nm.

4. The retardation film as claimed in claim 1, wherein the water-soluble polymer matrix is selected from one of the group consisting of polyol polymer, polyester polyol, polyurethane and polysiloxane, or combinations thereof.

5. The retardation film as claimed in claim 1, wherein the water-soluble dichroic dye is an azo compound or a salt thereof.

6. The retardation film as claimed in claim 1, wherein the amount of the water-soluble dichroic dye ranges from 0.1 wt % to 0.5 wt % based on the total weight of the water-soluble polymer matrix.

7. The retardation film as claimed in claim 1, wherein the thickness of the retardation film ranges from 5 μm to 100 μm.

8. A circular polarizer, comprising a retardation film as claimed in claim 1.

9. An electroluminescent display, comprising:
an electroluminescent display panel; and
a circular polarizer as claimed in claim 8 disposed on a light-emitting side of the electroluminescent display panel.

10. A circular polarizer, comprising a retardation film as claimed in claim 2.

11. An electroluminescent display, comprising:
an electroluminescent display panel; and
a circular polarizer as claimed in claim 10 disposed on a light-emitting side of the electroluminescent display panel.

12. A circular polarizer, comprising a retardation film as claimed in claim 3.

13. An electroluminescent display, comprising:
an electroluminescent display panel; and
a circular polarizer as claimed in claim 12 disposed on a light-emitting side of the electroluminescent display panel.

14. A circular polarizer, comprising a retardation film as claimed in claim 4.

15. An electroluminescent display, comprising:
an electroluminescent display panel; and
a circular polarizer as claimed in claim 14 disposed on a light-emitting side of the electroluminescent display panel.

16. A circular polarizer, comprising a retardation film as claimed in claim 5.

17. An electroluminescent display, comprising:
an electroluminescent display panel; and
a circular polarizer as claimed in claim 16 disposed on a light-emitting side of the electroluminescent display panel.

18. A circular polarizer, comprising a retardation film as claimed in claim 6.

19. An electroluminescent display, comprising:
an electroluminescent display panel; and
a circular polarizer as claimed in claim 18 disposed on a light-emitting side of the electroluminescent display panel.

20. A circular polarizer, comprising a retardation film as claimed in claim 7.

21. An electroluminescent display, comprising:
an electroluminescent display panel; and
a circular polarizer as claimed in claim 20 disposed on a light-emitting side of the electroluminescent display panel.
